(19) United States
(12) Patent Application Publication
(10) Pub. No.: US 2012/0043624 A1
(43) Pub. Date: Feb. 23, 2012

(54) ULTRA-THIN BODY TRANSISTOR AND METHOD FOR MANUFCTURING THE SAME

(76) Inventors: Qingqing Liang, Beijing (CN); Huicai Zhong, Beijing (CN); Huilong Zhu, Poughkeepsie, NY (US)

(21) Appl. No.: 13/132,535

(22) PCT Filed: Jan. 27, 2011
(86) PCT No.: PCT/CN11/70686

§ 371 Date: Jun. 2, 2011

(30) Foreign Application Priority Data
Aug. 18, 2010 (CN) CN201010257023.2

(51) Int. Cl. H01L 29/772; H01L 21/336

(52) U.S. Cl. 257/410; 257/412; 257/288; 438/300; 438/285; 257/E29.242; 257/E21.409

(57) ABSTRACT

An ultra-thin body transistor and a method for manufacturing an ultra-thin body transistor are disclosed. The ultra-thin body transistor comprises: a semiconductor substrate; a gate structure on the semiconductor substrate; and a source region and a drain region in the semiconductor substrate and on either side of the gate structure; in which the gate structure comprises a gate dielectric layer, a gate embedded in the gate dielectric layer, and a spacer on both sides of the gate; the ultra-thin body transistor further comprises: a body region and a buried insulated region located sequentially under the gate structure and in a well region; two ends of the body region and the buried insulated region are connected with the source region and the drain region respectively; and the body region is isolated from other regions in the well region by the buried insulated region under the body region. The ultra-thin body transistor has a thinner body region, which decreases the short channel effect. In the method for manufacturing an ultra-thin body transistor together with the replacement-gate process, the forming of the buried insulated region is self-aligned with the gate, which reduces the parasitic resistance under the spacer.

This application is a Section 371 National Stage Application of International Application No. PCT/CN2011/070686, filed on Jan. 27, 2011, which claims the benefit of No. 201010257023.2, filed on Aug. 18, 2010, the entire contents of which are incorporated herein by reference in their entirety.

### BACKGROUND OF THE INVENTION

1. Field of the Invention

The present invention relates to the semiconductor field, and particularly relates to an ultra-thin body transistor and manufacturing method thereof.

2. Description of Prior Art

With continuous development of semiconductor manufacturing technology, number of devices integrated in one chip has increased from several hundreds to today's several hundreds of millions. The performance and complexity of ICs have been advanced to an unimaginable level. To meet the requirements of complexity and circuit density, the minimum feature size is decreasing. Currently, a MOS transistor has a minimum line width of less than 45 nm.

With the decreasing of minimum feature size, various novel MOS device structures are developed for better short channel control. There is disclosed a MOS transistor with raised source drain in the U.S. Pat. No. 7,569,443. FIG. 1 shows a MOS transistor with raised source/drain region. The raised source/drain region 105 is located in the semiconductor substrate 101 on respective side of the gate 103. When manufacturing the MOS transistor, well regions on both sides of the sacrificial gate need to be etched after forming the sacrificial gate, to form source/drain trench; then, a silicon germanium material is filled in the source/drain trench to form raised source/drain regions. The raised source/drain regions may introduce stress in the channel of the MOS transistor, which enhances the carrier mobility in the channel region and improves the current-driving capability of the MOS transistor. Also, replacement-gate process is employed to improve stress characteristics of the channel region in the MOS transistor. The replacement-gate process comprises: after forming the raised source drain, removing the sacrificial gate and refilling conductive materials to form a gate. The new gate further improves the stress characteristics of the channel and enhances the carrier mobility in the channel.

However, the body region of the MOS transistor is thick, which is more susceptible to the shot channel effect of the devices, thus limiting the further scaling down and performance improvement of the devices.

### SUMMARY OF THE INVENTION

An object of the present invention is to provide an ultra-thin body transistor and a method for manufacturing the same. The ultra-thin body transistor has a thinner body region, which decreases the length of the lateral depletion region under drain reverse bias, thus effectively suppressing the short channel effect.

To solve the above problem, there is provided an ultra-thin body transistor in the present invention. The ultra-thin body transistor comprises: a semiconductor substrate; a gate structure on the semiconductor substrate; and a source region and a drain region in the semiconductor substrate and on respective side of the gate structure; wherein the gate structure comprises a gate dielectric layer, a gate embedded in the gate dielectric layer, and a spacer on both sides of the gate; the ultra-thin body transistor further comprises: a body region and a buried insulated region located sequentially in a well region under the gate structure, wherein two ends of the body region and the buried insulated region are connected with the source region and the drain region, respectively, and other regions of the body region and the well region are isolated from each other by the buried insulated region under the body region.

There is also provided a method for manufacturing an ultra-thin body transistor in the present invention. The method comprises:

providing a semiconductor substrate having a buried sacrificial layer and a body region epitaxial layer thereon;

forming a trench isolation region in the semiconductor substrate and forming a well region in the semiconductor substrate in the trench isolation region, wherein the trench isolation region and the well region have a depth at least larger than that of the buried sacrificial layer;

forming a sacrificial gate dielectric layer, a sacrificial gate and a sacrificial gate protection cap layer sequentially on the well region;

forming a shallow doped region in the well region on both sides of the sacrificial gate, and forming a spacer on both sides of the sacrificial gate;

forming a source/drain opening in the semiconductor substrate outside the spacer of the sacrificial gate, wherein the source/drain opening has a depth at least larger than that of the buried sacrificial layer;

filling the source/drain opening with a heavily doped source/drain material to form a deep doped region;

forming an interlayer dielectric layer on the semiconductor substrate to cover the deep doped region and the sacrificial gate;

planarizing the interlayer dielectric layer to expose a surface of the sacrificial gate protection cap layer;

removing the sacrificial gate protection cap layer, the sacrificial gate and the sacrificial gate dielectric layer to form a gate opening;

performing an anisotropic etching to the trench isolation region under the original sacrificial gate to expose the buried sacrificial layer;

removing the buried sacrificial layer, and forming a buried cavity in a position where the original buried sacrificial layer is located; and

filling up the buried cavity with a buried dielectric material to form a buried insulated region.

In comparison with conventional technologies, the present invention has the following advantages:

1. The ultra-thin body transistor has a thinner body region, which decreases the effect to the effective length of channel caused by the lateral depletion region under drain reverse bias;

2. The forming of the buried insulated region is self-aligned with the gate, which reduces the parasitic resistance under the spacer; the body region is isolated from the well region by the buried insulated region, which avoids the substrate bias effects to the device performance.

### BRIEF DESCRIPTION OF THE DRAWINGS

FIG. 1 is a schematic view of a MOS transistor with raised source/drain regions;

FIG. 2 to FIG. 4 are schematic views of an ultra-thin body transistor in an embodiment of the present invention;

FIG. 5 is a flow chart of a method for manufacturing an ultra-thin body transistor in an embodiment of the present invention; and

FIG. 6 to FIG. 21 are cross-sectional views of an ultra-thin body transistor in intermediate stages of the method for manufacturing an ultra-thin body transistor in the embodiment of the present invention.

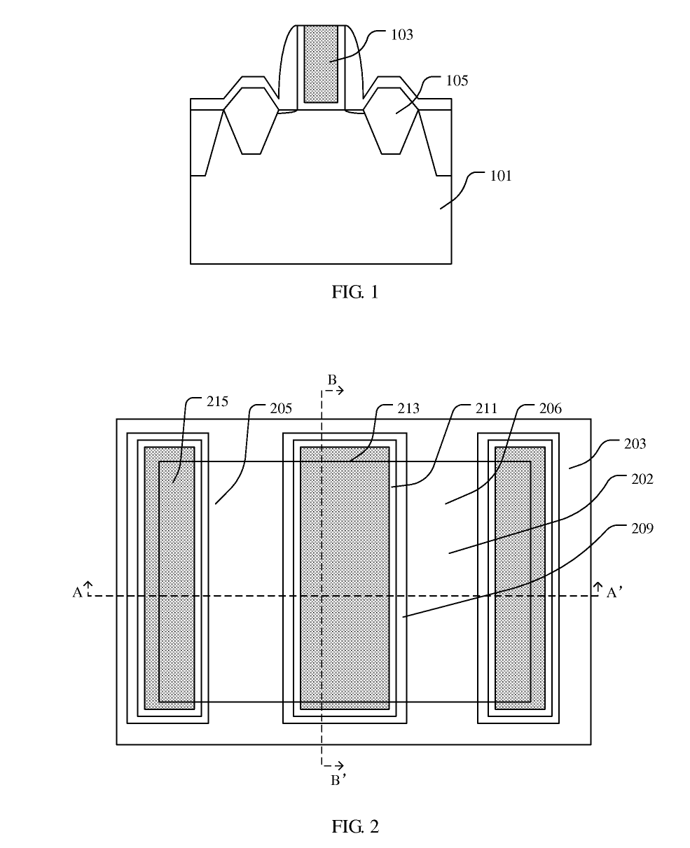

### DETAILED DESCRIPTION OF THE EMBODIMENTS

The present invention will be described hereafter in detail with reference to embodiments, in conjunction with the accompanying drawings.

Embodiments to which the present invention is applied are described in detail below. However, the invention is not restricted to the embodiments described below.

As described in the background, conventional MOS transistors have thick body regions, which are subject to the short channel effects and restricts further improvement of device performance. To solve this problem, the present invention provides a MOS transistor with ultra-thin body regions. The ultra-thin body transistor has a buried insulated region formed in the substrate. The buried insulated region isolates the body region under the gate from the substrate. Therefore, the thickness of the body region of the ultra-thin body transistor is greatly decreased, which greatly suppress the short channel effect.

In addition, for the ultra-thin body transistor provided in the present invention, replacement-gate process is used to form a gate and a gate dielectric layer under the gate of the MOS transistor. The newly formed gate further improves the stress characteristics of the channel region, which enhances the carrier mobility in the channel region and improves the current driving capability of the MOS transistor.

Hereafter, the ultra-thin body transistor and the method for manufacturing the same will be described in detail with reference to embodiments, in conjunction with the accompanying drawings.

FIG. 2 is a top view of an ultra-thin body transistor in an embodiment of the present invention.

Referring to FIG. 2, the ultra-thin body transistor comprises: a semiconductor substrate 201; a well region 202 in the semiconductor substrate 201; a trench isolation region 203 being located outside the well region 202 and surrounding the well region 202; a gate 213 being disposed across the well region 202 with two ends located on the trench isolation region 203; a gate dielectric layer 211 and a spacer 209 on the semiconductor substrate 201 on both sides of the gate 213; and a source region 205 and a drain region 206 in the well region 202 on respective side of the gate. The ultra-thin body transistor further comprises a body region and a buried insulated region (not shown in FIG. 2) sequentially under the gate 213. In this embodiment, the ultra-thin body transistor further comprises two dummy-gates 215 on both sides of the source and drain region, respectively. The dummy-gates 215 are parallel to the gate 213 with one part on the trench isolation region 203 and the other part on the well region 202.

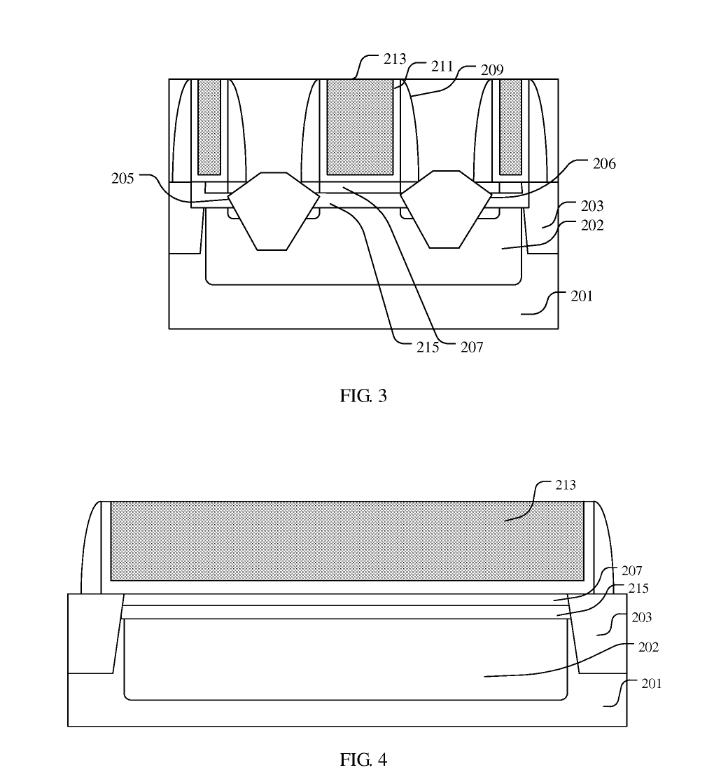

FIG. 3 is a cross-sectional view taken along line A-A′ in FIG. 2. The gate structure of the ultra-thin body transistor comprises a gate dielectric layer 211, a gate 213 embedded in the gate dielectric layer 211, and a spacer 209 on both sides of the gate 213. The gate 213 is isolated from the spacer 209 and the well region 202 by the gate dielectric layer 211.

In this embodiment, the source region 205 and the drain region 206 have raised surfaces compared with the surface of the semiconductor substrate 201. A body region 207 and a buried insulated region 215 are located under the gate structure. Two ends of the body region 207 and the buried insulated region 215 are connected with the source region 205 and the drain region 206, respectively. The body region 207 is isolated from other regions in the well region 202 by the buried insulated region 215. The depth of the source region 205 and the drain region 206 is at least larger than the depth of the buried insulated region 215.

FIG. 4 is a cross-sectional view taken along line B-B′ in FIG. 2. Referring to FIG. 4, the gate 213 is disposed across the well region 202, with two ends located on the trench isolation region 203 on both sides of the well region 202. In addition, the buried insulated region 215 and the body region 207 have their two ends connected with the trench isolation region 203, respectively.

In this embodiment, the semiconductor substrate 201 is made of silicon, germanium, SiGe, gallium nitride or other semiconductor materials. The source region 205 and the drain region 206 are made of SiGe or other semiconductor materials which can be grown on the semiconductor substrate 201 using epitaxy process. According to different embodiments, the surfaces of the source region 205 and the drain region 206 may not be raised surfaces, and may be flushed with other surfaces in the well region 202.

Similar to the conventional MOS transistor, the source region 205 and the drain region 206 may have the same doping configuration which is opposite to that of the body region 207. Both source region 205 and drain region 206 have a shallow doped region and a deep doped region. The deep doped region, which is located in the well region 202, extends to under the spacer 209 and is aligned with the edge of the gate 213. The shallow doped region, which is located in the well region 202 under the spacer 209, has a depth larger than that of the body region 207.

The buried insulated region 215 is made of silicon oxide, the spacer 209 is made of silicon nitride, and the buried insulated region 215 has a thickness of 20 nm to 100 nm; the body region 205 is made of silicon, SiGe or other semiconductor materials, which has a thickness of 5 nm to 20 nm.

The gate dielectric layer 211 is made of silicon oxide, silicon oxynitride or high-k dielectric materials. The gate 213 is made of doped polycrystalline silicon, metal materials, or other conductive materials.

Compared with the conventional MOS transistors, the ultra-thin body transistor of the present invention has a much thinner body region, which improves the control of the short channel effect caused by the lateral depletion region under drain reverse bias. In addition, the forming of the buried insulated region is self-aligned with the gate, which reduces the parasitic resistance under the spacer. The body region is isolated from the well region by the buried insulated region, which avoids the substrate bias effects to the device performance.

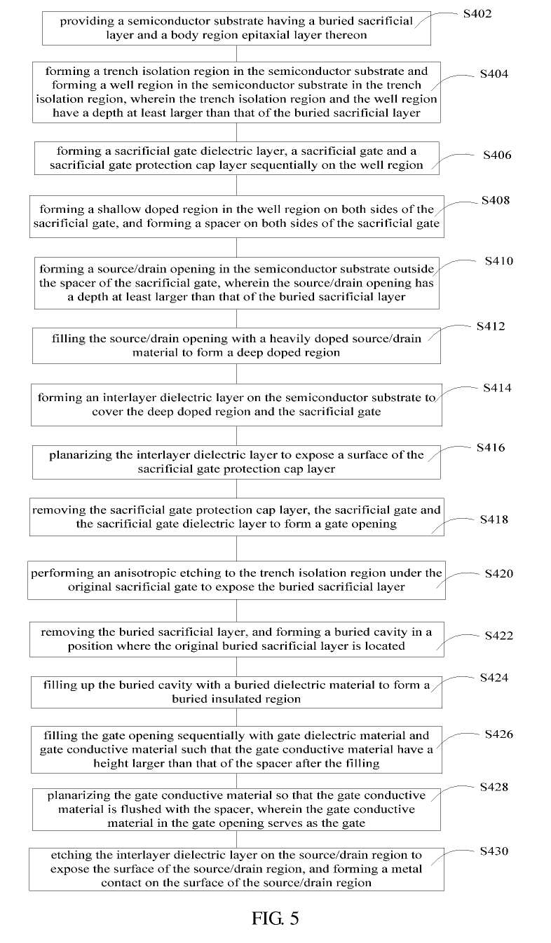

Based on the above-described ultra-thin body transistor, there is also provided a method for manufacturing an ultra-thin body transistor. Referring to FIG. 5, the method comprises the follow steps:

S402, providing a semiconductor substrate comprising a buried sacrificial layer and a body region epitaxial layer thereon;

S404, forming a trench isolation region in the semiconductor substrate, and forming a well region in the semiconductor substrate in the trench isolation region, wherein the trench isolation region and the well region have a depth at least larger than that of the buried sacrificial layer;

S406, forming a sacrificial gate dielectric layer, a sacrificial gate and a sacrificial gate protection cap layer sequentially on the well region;

S408, forming a shallow doped region in the well region on both sides of the sacrificial gate, and forming a spacer on both sides of the sacrificial gate;

S410, forming a source/drain opening in the semiconductor substrate outside the spacer of the sacrificial gate, wherein the source/drain opening have a depth at least larger than that of the buried sacrificial layer;

S412, filling the source/drain opening with heavily doped source/drain materials to form a deep doped region;

S414, forming an interlayer dielectric layer on the semiconductor substrate to cover the deep doped region and the sacrificial gate;

S416, planarizing the interlayer dielectric layer to expose the surface of the sacrificial gate protection cap layer;

S418, removing the sacrificial gate protection cap layer, the sacrificial gate and the sacrificial gate dielectric layer to form a gate opening;

S420, performing anisotropic etching to the trench isolation region under the original sacrificial gate to expose the buried sacrificial layer;

S422, removing the buried sacrificial layer, and forming a buried cavity in a position of the original buried sacrificial layer;

S424, filling the buried cavity with buried dielectric material to form a buried insulated region;

S426, filling the gate opening sequentially with gate dielectric material and gate conductive material such that the gate conductive material have a height larger than that of the spacer after the filling;

S428, planarizing the gate conductive material so that the gate conductive material is flushed with the spacer, wherein the gate conductive material in the gate opening serves as the gate; and

S430, etching the interlayer dielectric layer on the source/drain region to expose the surface of the source/drain region, and forming a metal contact on the surface of the source/drain region.

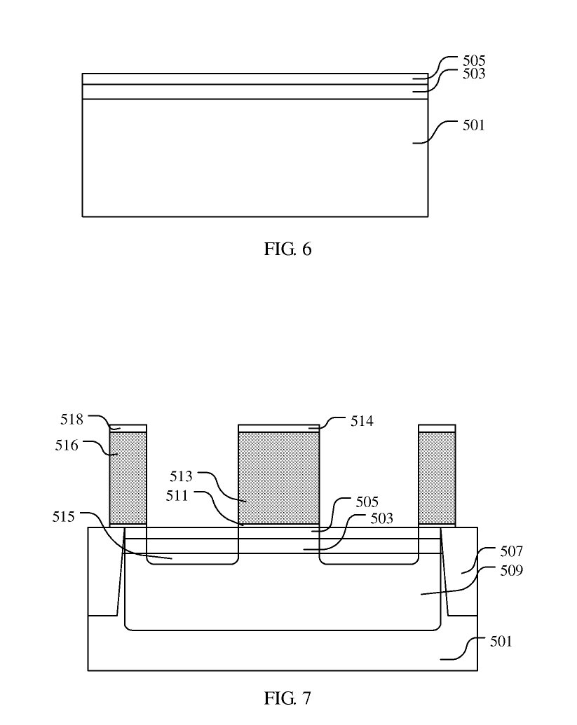

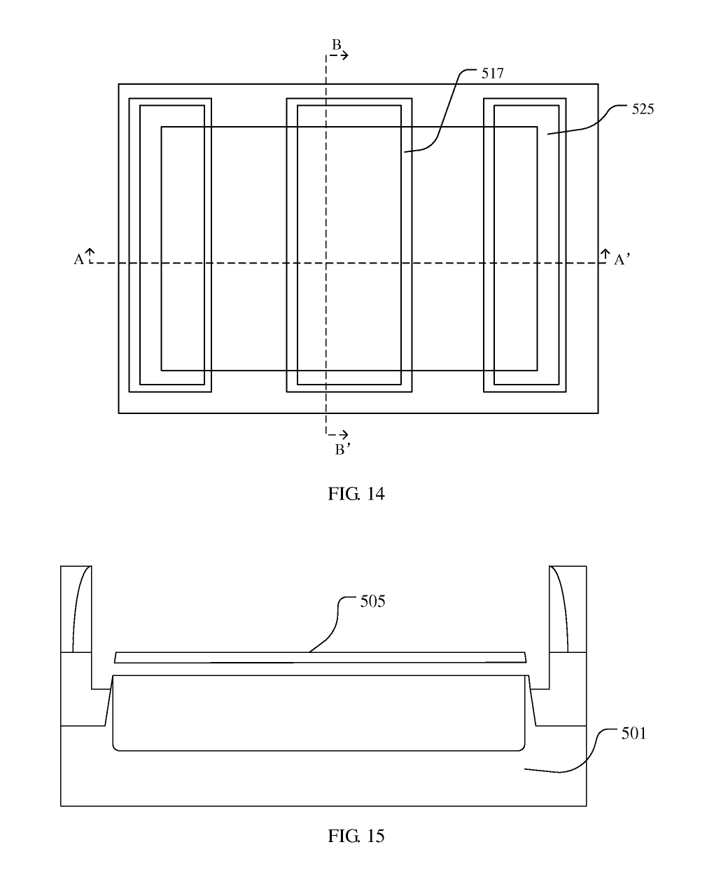

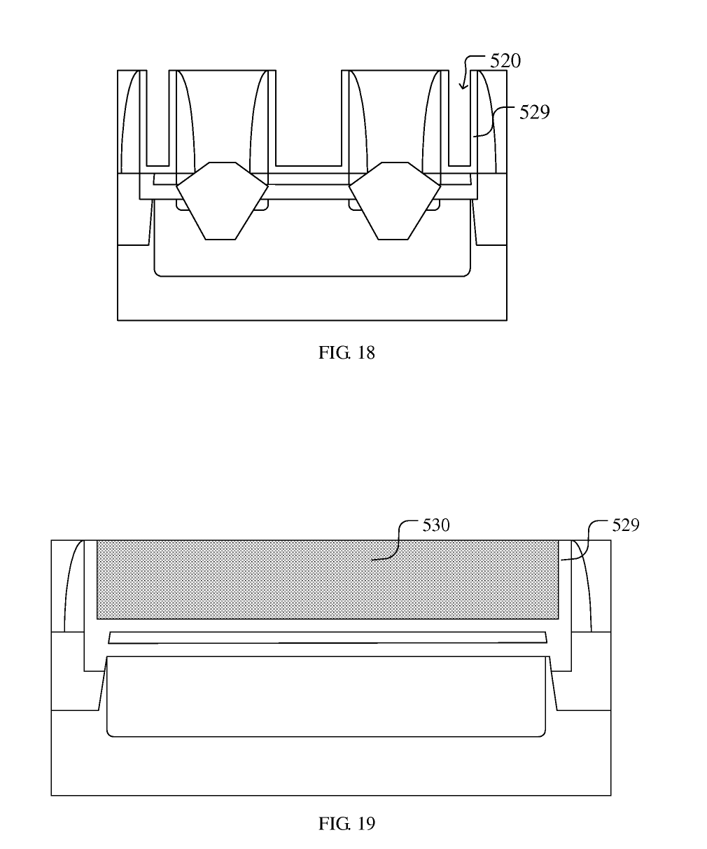

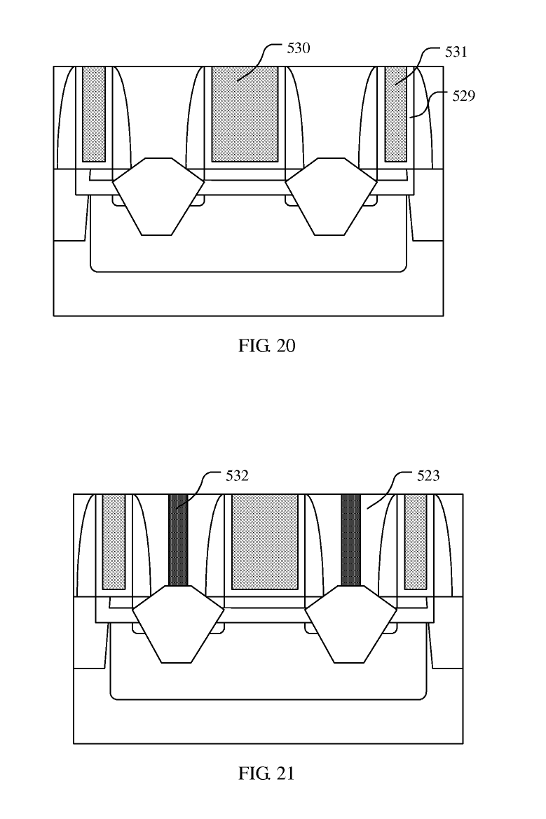

FIG. 6 to FIG. 21 illustrate different stages of the method for manufacturing the ultra-thin body transistor in the embodiment of the present invention, in which FIG. 6 to FIG. 13, FIG. 18 and FIG. 20 are cross-sectional views taken along line A-A′ in FIG. 2, FIG. 15 to FIG. 17 and FIG. 19 are cross-sectional views taken along line B-B′ in FIG. 2, and FIG. 14 is a top view of a semiconductor substrate after forming a buried cavity.

Referring to FIG. 6, a semiconductor substrate 501 is provided, and a buried sacrificial layer 503 and a body region epitaxial layer 505 are sequentially formed on the semiconductor substrate 501.

The body region epitaxial layer 505 needs to be a monocrystal structure, since it is used to form the body region of the ultra-thin body transistor. Therefore, in this embodiment, the body region epitaxial layer 505 and the buried sacrificial layer 503 are formed by epitaxial process such as molecular beam epitaxial growth, atomic layer deposition and chemical vapor deposition. Both the body region epitaxial layer 505 and the buried sacrificial layer 503 are monocrystal structures. Preferably, the body region epitaxial layer 505 and the buried sacrificial layer 503 have matching lattice constants to avoid stress mismatch.

In some embodiments of the present invention, the semiconductor substrate 501 is made of silicon, germanium, SiGe, gallium nitride or other semiconductor materials; the buried sacrificial layer 503 is made of silicon carbide, SiGe or other semiconductor materials, and has a thickness of 20 nm to 100 nm; and the body region epitaxial layer 505 is made of silicon, SiGe or other semiconductor materials, and has a thickness of 5 nm to 50 nm.

As illustrated in FIG. 7, a trench isolation region 507 is formed in the semiconductor substrate 501. The trench isolation region 507 extends through the body region epitaxial layer 505 and the buried sacrificial layer 503 to the inside of the semiconductor substrate 501. In some embodiments of the present invention, the trench isolation region 507 is a shallow trench isolation structure (STI).

Then, ion implantation is performed to the semiconductor substrate 501 to form a well region 509 in the semiconductor substrate 501 in the trench isolation region 507. The well region 509 has a depth at least larger than that of the buried sacrificial layer 503.

After the trench isolation region 507 and the well region 509 are formed, a sacrificial gate dielectric layer 511, a sacrificial gate 513 and a sacrificial gate protection cap layer 514 are formed sequentially on the body region epitaxial layer 505; and a sacrificial gate dielectric layer 511, a trench protection layer 516 and a trench protection cap layer 518 are formed sequentially on the border of the trench isolation region 507 and the well region 509 parallel to the sacrificial gate 513. The sacrificial gate dielectric layer 511 and the sacrificial gate 513 are mainly located in the well region 509; and the two ends of the sacrificial gate 513 are on the trench isolation region 507 outside the well region 509. The trench protection layer 516 and the sacrificial gate 513 are made of the same material; and the sacrificial gate protection cap layer 514 and the trench protection cap layer 518 are made of the same material. In some embodiments of the present invention, the gate dielectric layer 511 is made of dielectric materials such as silicon oxide; the sacrificial gate 513 and the trench protection layer 516 are made of polycrystalline silicon; and the sacrificial gate protection cap layer 514 and the trench protection cap layer 518 are made of silicon nitride.

Then, ion implantation is performed to the semiconductor substrate 501 to form shallow doped regions 515 on both sides of the sacrificial gate 513. In some embodiments of the present invention, the shallow doped regions 515 may have a depth larger than that of the body region epitaxial layer 505 and extend into the buried sacrificial layer 503 or the well region 509.

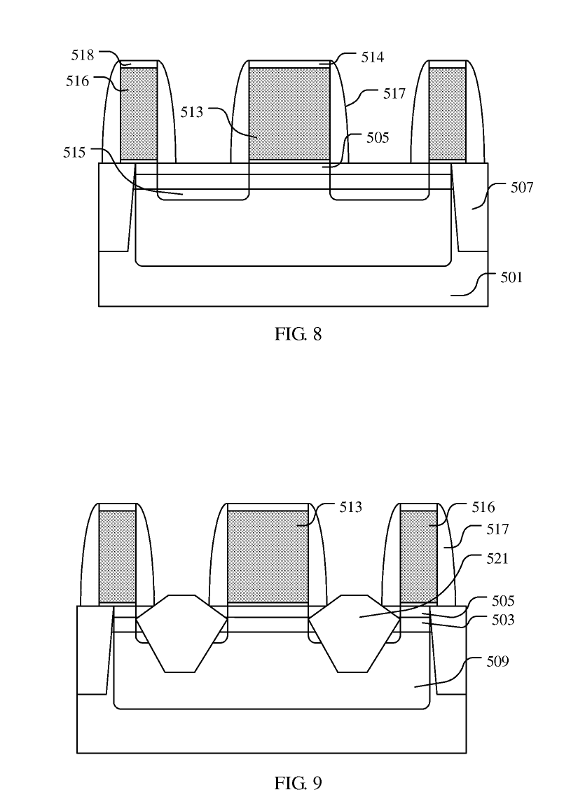

As illustrated in FIG. 8, a spacer dielectric layer is formed on the semiconductor substrate 501 to cover the trench isolation region 507, the sacrificial gate protection cap layer 514, the trench protection cap layer 518 and the body region epitaxial layer 505. The spacer dielectric layer is made of silicon nitride, silicon oxynitride or other dielectric materials. Preferably, the spacer dielectric layer is made of a material which has a high etching selectivity relative to the trench isolation region 507. For example, the trench isolation region 507 is made of silicon oxide, and the spacer dielectric layer is made of silicon nitride. Then, an anisotropic etching is performed to the spacer dielectric layer to form a spacer 517 on the body region epitaxial layer 505 on both sides of the sacrificial gate 513, and on the body region epitaxial layer 505 and the trench isolation region 509 on both sides of the trench protection layer 516.

As illustrated in FIG. 9, anisotropic etching is performed to the shallow doped region and portions of the well region 509 under the shallow doped region to form a source/drain opening, with the spacer 517, the sacrificial gate 513 and the trench protection layer 516 as a mask. For example, anisotropic dry etching is performed to the shallow doped region by SF6 gas. The anisotropic etching is performed to avoid defects caused by laterally etching the shallow doped region under the spacer 517.

In some embodiments of the present invention, the source/drain opening has an etching depth not larger than the depth of the well region 509 to prevent the subsequently formed source/drain region from being connected with the semiconductor substrate outside the well region 509.

Then, an epitaxial growth of heavily doped source/drain material is performed in the source/drain opening to fill up the source/drain opening. The source/drain material in the source/drain opening is used as deep doped region 521 of the ultra-thin body transistor. Since other regions on the semiconductor substrate are covered with dielectric materials and only the source/drain opening is filled with semiconductor materials, the source/drain material is only filled into the source/drain opening.

In this embodiment, the formed source/drain region extends to bottom of the spacer 517 to occupy the position under the spacer 517 where the original buried sacrificial layer 503 is located. In this way, the buried sacrificial layer 503 is self-aligned with the gate 513, which reduces the parasitic resistance under the spacer 503.

In different embodiments, the heavily doped source/drain material can be made by in-situ doping, or by firstly performing epitaxial growth of intrinsic semiconductor material and then performing ion implantation for heavily doping. In a preferred embodiment, the source/drain material and the body region epitaxial layer 505 are made of the same semiconductor material.

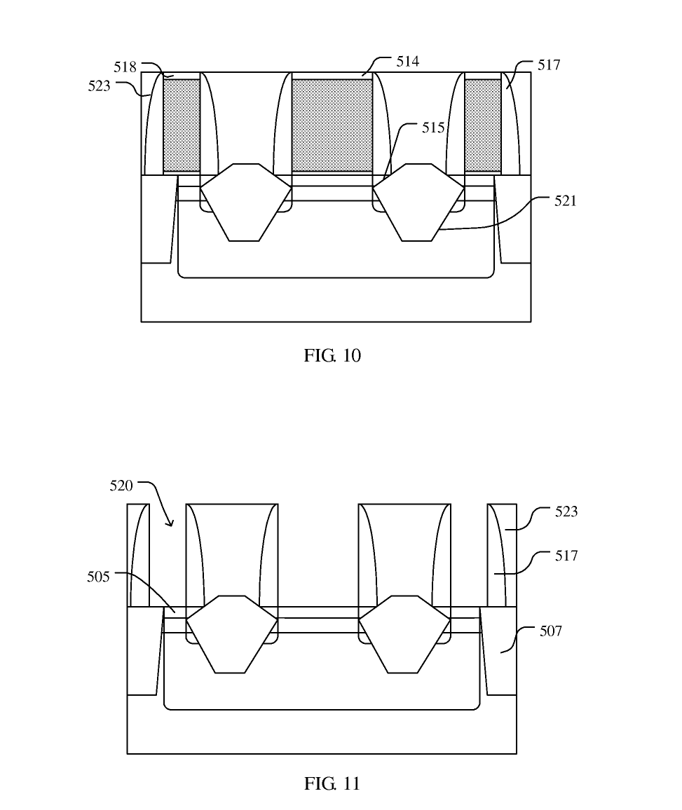

Referring to FIG. 10, the shallow doped region 515 and the deep doped region 521 together constitute the source/drain region of the ultra-thin body transistor. After the source/drain region is formed, an interlayer dielectric layer 523 is formed on the source/drain region, the sacrificial gate protecting cap layer 514, the spacer 517 and the trench protection cap layer 518. The interlayer dielectric layer 523 has a height at least higher than the surface of the sacrificial gate protecting cap layer 514. Then, the interlayer dielectric layer 523 is planarized to expose the surfaces of the sacrificial gate protecting cap layer 514 and the trench protection cap layer 518.

In this embodiment, the interlayer dielectric layer 523 is made of a dielectric material having a high etching selectivity relative to the trench isolation region 507, such as silicon nitride, and serves as a mask for subsequently etching the trench isolation region 507.

As illustrated in FIG. 11, the sacrificial gate protection cap layer, the sacrificial gate, the trench protection layer, the trench protection cap layer and the sacrificial gate dielectric layer are removed to form a gate opening 520 between the spacer 517, with the interlayer dielectric layer 523 and the spacer 517 as a mask. Since portions of original the sacrificial gate and the trench protection layer partially cover the trench isolation region 507, the surfaces of the trench isolation region 507 and the body region epitaxial layer 505 are partially exposed by the removing process. In different embodiments, the sacrificial gate protecting cap layer, trench protection cap layer, sacrificial gate and the trench protection layer may be removed by a dry etching process or a wet etching process.

In a dry etching process, the sacrificial gate of polycrystalline silicon can be etched by a plasma gas containing SF₆, HBr, Cl₂ and inert gas. In a wet etching process, the sacrificial gate can be etched by tetramethylammonium hydroxide (TMAH) solution at a temperature of 60 to 90.

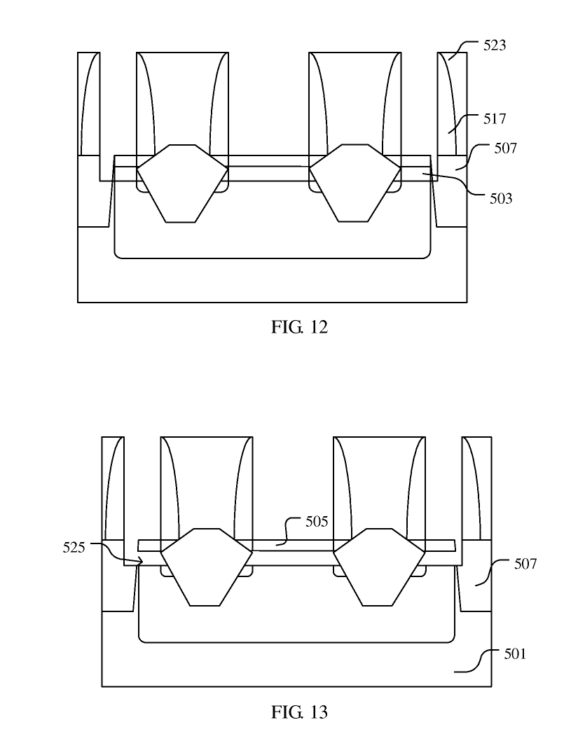

Referring to FIG. 12, after completely removing the sacrificial gate and the sacrificial gate dielectric layer under the sacrificial gate, the exposed trench isolation region 507 is partially etched to expose the side of the buried sacrificial layer 503 is exposed, with the interlayer dielectric layer 523 and the spacer 517 as a mask. Since the interlayer dielectric layer 523 and the spacer 517 are made of a different dielectric material from the trench isolation region 507, the etching to the trench isolation region 507 does not affect the interlayer dielectric layer 523 and the spacer 517.

Referring to FIG. 13, the exposed buried sacrificial layer is removed by an isotropic dry or wet etching process, to form a buried cavity 525. The buried cavity 525 makes the body region epitaxial layer 505 partially suspended over the semiconductor substrate. However, since the buried sacrificial layer at the position where the source/drain region is located has been removed when forming the source/drain region, the source/drain region can be used to support the partially suspended body region epitaxial layer 505.

In some embodiments of the present invention, the buried sacrificial layer is made of a material which has a high etching selectivity relative to the semiconductor substrate 501, the body region epitaxial layer 505, the spacer 517, the source/drain region and the trench isolation region 507. The buried sacrificial layer may be made of silicon carbide in a case where the semiconductor substrate 501 and the body region epitaxial layer 505 are made of silicon, the spacer 517 is made of silicon nitride, and the trench isolation region 507 is made of silicon oxide; and accordingly, the buried sacrificial layer is etched with a mixed solution of hydrochloric acid and hydrofluoric acid.

FIG. 14 is a top view of a semiconductor substrate after forming a buried cavity. Referring to FIG. 14, the trench isolation region in the spacer 517 is removed so that the etching gas or etching liquid may enter into the semiconductor substrate. As a result, the buried sacrificial layer may be removed by the etching gas or etching liquid to form the buried cavity 525.

FIG. 13 is a cross-sectional view of the semiconductor substrate taken along line A-A′ in FIG. 14; and FIG. 15 is a cross-sectional view of the semiconductor substrate taken along line B-B′ in FIG. 14.

Referring to FIG. 15, the buried sacrificial layer under the original sacrificial gate is completely removed, and the body region epitaxial layer 505 is suspended over the semiconductor substrate 501.

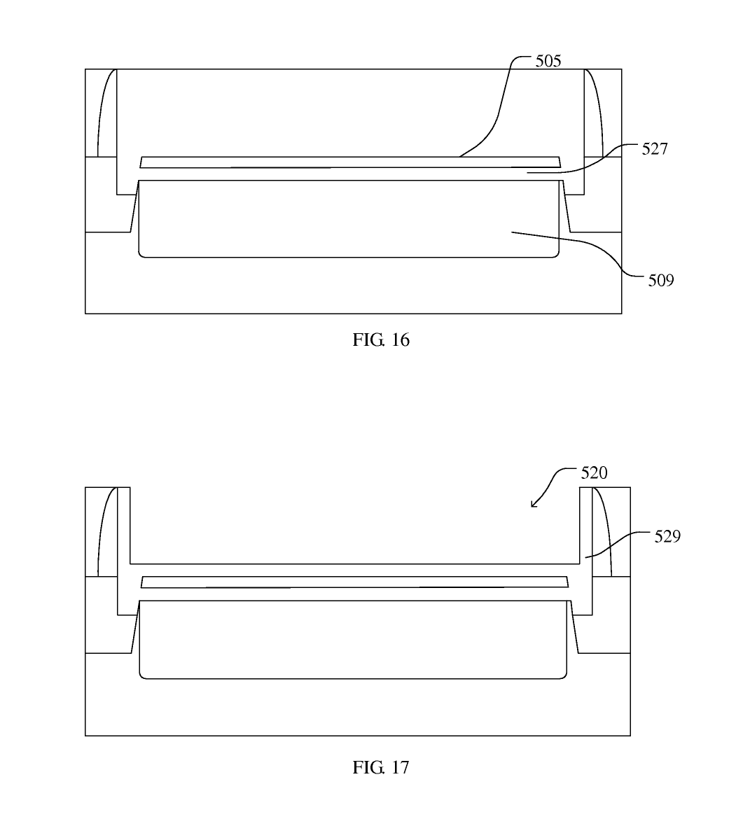

Referring to FIG. 16, a buried dielectric material is filled up in the buried cavity to form a buried insulated region 527. The buried insulated region 527, which replaces the original buried sacrificial layer, is used as an isolation structure between the body region epitaxial layer 505 and the well region 509.

To ensure the filling quality of the buried insulated region 527, the buried cavity and the position of the original sacrificial gate need to be overly filled. Therefore, in this embodiment, during the filling of the buried cavity, a dielectric material is also formed in the position where the sacrificial gate is located. The overly filled dielectric material may be planarized to be flushed with the interlayer dielectric layer and the spacer. Then, the dielectric material in the position where the sacrificial gate is located is etched to expose the body region epitaxial layer 505, so as to form the gate opening again.

In some embodiments of the present invention, the buried insulated region 527 is formed by a film manufacturing process which has better filling capability, such as atomic layer deposition and low pressure chemical vapor deposition, to prevent defects caused by incomplete filling of the buried cavity which may affect the device performance. The buried insulated region 527 may be made of materials which have a high etching selectivity relative to the interlayer dielectric layer, for example, the buried insulated region 527 is made of silicon oxide.

In this embodiment, the buried insulated region 527 and the buried sacrificial layer have the same thickness from 20 nm to 100 nm.

Referring to FIG. 17 and FIG. 18, after filling the buried insulated region 527, a gate dielectric layer 529 is formed by depositing a gate dielectric material in the gate opening 520. The gate dielectric material may be silicon oxide, silicon oxynitride or high-k dielectric materials.

Referring to FIG. 19 and FIG. 20, after forming the gate dielectric layer 529, the gate conductive material is filled in the gate opening, so that the gate conductive material has a height higher than the top surface of the spacer after the filling.

Then, the gate conductive material is planarized to be flushed with the spacer. The gate conductive material in the gate opening serves as the gate or dummy-gate. The gate conductive material between the source/drain regions is the gate 530; and the gate conductive material on the trench isolation region 507 outside the source/drain region is the dummy-gate 531.

Referring to FIG. 21, the interlayer dielectric layer 523 is partially etched to expose the surface of the source/drain region, and a metal contact 32 is formed on the surface of the source/drain region.

After the above steps, the ultra-thin body transistor in this embodiment of the present invention is formed completely. In some embodiments, contact holes are formed to connect to the source region, the drain region and the gate.

In the method for manufacturing the ultra-thin body transistor according to the present invention, the buried insulated region under the body region is formed by forming a buried sacrificial layer in the semiconductor substrate and then replacing the buried sacrificial layer. The above method is compatible with the conventional manufacturing process of MOS transistors, which achieves a thinner body region in a simple way.

Although the present invention has been illustrated and described with reference to the preferred embodiments of the present invention, those ordinary skilled in the art shall appreciate that various modifications in form and detail may be made without departing from the spirit and scope of the invention.

What is claimed is:

1. An ultra-thin body transistor, comprising:
a semiconductor substrate;
a gate structure on the semiconductor substrate; and
a source region and a drain region in the semiconductor substrate on respective side of the gate structure;
characterized in that
the gate structure comprises a gate dielectric layer, a gate embedded in the gate dielectric layer, and a spacer on both sides of the gate; and
the ultra-thin body transistor further comprises: a body region and a buried insulated region located sequentially in a well region under the gate structure, wherein two ends of the body region and the buried insulated region are connected with the source region and the drain region, respectively, and other regions of the body region and the well region are isolated from each other by the buried insulated region under the body region.

2. The ultra-thin body transistor of claim 1, wherein the source region and the drain region have raised surfaces compared with the semiconductor substrate.

3. The ultra-thin body transistor of claim 1, wherein the source region and the drain region have a depth larger than that of the buried insulated region.

4. The ultra-thin body transistor of claim 1, wherein the source region and the drain region each has a shallow doped region and a deep doped region, wherein the shallow doped region has a depth larger than that of the body region, and the deep doped region extends to under the spacer.

5. The ultra-thin body transistor of claim 1, wherein the buried insulated region is made of silicon oxide, and the spacer is made of silicon nitride.

6. The ultra-thin body transistor of claim 1, characterized in that the buried insulated region has a thickness of 20 nm to 100 nm.

7. The ultra-thin body transistor of claim 1, wherein the body region has a monocrystal structure, and is made of silicon or SiGe.

8. The ultra-thin body transistor of claim 1, wherein the body region has a thickness of 5 nm to 50 nm.

9. The ultra-thin body transistor of claim 1, wherein the gate dielectric layer is made of at least one of silicon oxide, silicon nitride and high-k dielectric materials.

10. The ultra-thin body transistor of claim 1, wherein the gate is made of metal materials or doped polycrystalline silicon.

11. A method for manufacturing an ultra-thin body transistor, comprising:
providing a semiconductor substrate having a buried sacrificial layer and a body region epitaxial layer thereon;
forming a trench isolation region in the semiconductor substrate and forming a well region in the semiconductor substrate in the trench isolation region, wherein the trench isolation region and the well region have a depth at least larger than that of the buried sacrificial layer;
forming a sacrificial gate dielectric layer, a sacrificial gate and a sacrificial gate protection cap layer sequentially on the well region;
forming a shallow doped region in the well region on both sides of the sacrificial gate, and forming a spacer on both sides of the sacrificial gate;
forming a source/drain opening in the semiconductor substrate outside the spacer of the sacrificial gate, wherein the source/drain opening has a depth at least larger than that of the buried sacrificial layer;
filling the source/drain opening with a heavily doped source/drain material to form a deep doped region;
forming an interlayer dielectric layer on the semiconductor substrate to cover the deep doped region and the sacrificial gate;
planarizing the interlayer dielectric layer to expose a surface of the sacrificial gate protection cap layer;
removing the sacrificial gate protection cap layer, the sacrificial gate and the sacrificial gate dielectric layer to form a gate opening;
performing an anisotropic etching to the trench isolation region under the original sacrificial gate to expose the buried sacrificial layer;
removing the buried sacrificial layer, and forming a buried cavity in a position where the original buried sacrificial layer is located; and
filling up the buried cavity with a buried dielectric material to form a buried insulated region.

12. The method of claim 11, wherein the semiconductor substrate is made of silicon, germanium, SiGe or gallium nitride.

13. The method of claim 11, wherein the buried sacrificial layer and the body region epitaxial layer each have a monocrystal structure, and the buried sacrificial layer and the body region epitaxial layer both in monocrystal structure are formed by an epitaxial process.

14. The method of claim 11, wherein the buried sacrificial layer is made of silicon carbide or SiGe.

15. The method of claim 11, wherein the buried sacrificial layer has a thickness of 20 nm to 100 nm.

16. The method of claim 11, wherein the body region epitaxial layer is made of silicon or SiGe.

17. The method of claim 11, wherein the body region epitaxial layer has a thickness of 5 nm to 50 nm.

18. The method of claim 11, wherein the shallow doped region has a depth larger than that of the body region epitaxial layer.

19. The method of claim 11, wherein the semiconductor substrate is etched anisotropically to form the source/drain opening, and the source/drain opening has an etching depth larger than that of the well region.

20. The method of claim 11, wherein the heavily doped source/drain material is formed by a method of in-situ doping and selective epitaxial growth, or by ion implantation for heavily doping.

21. The method of claim 11, wherein the buried sacrificial layer is removed by isotropic etching or wet etching to form the buried cavity.

22. The method of claim 11, wherein the buried cavity is filled by atomic layer deposition or low pressure chemical vapor deposition to form the buried insulated region.

23. The method of claim 11, wherein the gate structure of the ultra-thin body transistor is formed by a replacement gate process, which comprises:
filling the gate opening sequentially with a gate dielectric material and a gate conductive material so that the gate conductive material has a height larger than that of the spacer after the filling; and
planarizing the gate conductive material so that the gate conductive material is flushed with the spacer, wherein the gate conductive material in the gate opening serves as the gate.

24. The method of claim 23, wherein the gate dielectric material is at least one selected from a group comprising silicon oxide, silicon nitride and high-k dielectric materials.
